(19) United States
(12) Patent Application Publication
(10) Pub. No.: US 2010/0276603 A1
(43) Pub. Date: Nov. 4, 2010

(54) RADON DETECTOR AND CONTINUOUS DETECTION DEVICE INCLUDING SUCH DETECTOR

(75) Inventors: Isabelle Niort, Nieul (FR); Jean-Louis Decossas, Cieux (FR)

Correspondence Address: YOUNG & THOMPSON, 209 Madison Street, Suite 500, Alexandria, VA, 22314, US

(73) Assignee: PE@RL, Limoges (FR)

(21) Appl. No.: 12/812,079

(22) PCT Filed: Jan. 9, 2009
(86) PCT No.: PCT/FR09/50029

§ 371 Date: Jul. 8, 2010

(30) Foreign Application Priority Data
Jan. 10, 2008 (FR) 08 50119

(51) Int. Cl. G01T 1/24; H01L 31/00

(52) U.S. Cl. 250/370.06; 250/370.14; 257/429; 257/E31.001

(57) ABSTRACT

The object of the invention is a detector (20) of radon and its daughter products that are present in the ambient air, including in particular aerosols, characterized in that it comprises:

A silicon pellet that integrates a PN junction with a deserted zone, designed to emit signals under the action of the radiation that is emitted by said radon and said daughter products,

A passivation layer (22) that covers this silicon pellet and that makes it possible for the detector to work in the open air, and

A conductive layer (24) that covers the passivation layer and that forms an electrode for collecting radionuclides.

The invention also covers the detection device that includes said detector.

This invention relates to a radon detector as well as the detection device integrating said detector. Radon is an inert and radioactive gas that is odorless, tasteless, colorless and therefore undetectable by human senses.

Radon is a natural gas that essentially results from the disintegration of the uranium that is omnipresent in all rocks and soils over the entire planet.

Soils release radon. When it disintegrates, it yields related products, also called daughter products, for example Polonium 218 and Polonium 214.

Radon by itself represents only a slight health risk because it is inhaled and exhaled quickly without settling in the lungs; the miniscule portion that may possibly pass into the blood and then into the body does not produce significant risks of cancer development.

In contrast, short-term daughter products, with a life of less than one hour and that emit radiation and in particular alpha particles, tend to become attached to dust and air particles, aerosols and/or smoke particles that can be deposited on the walls of the respiratory tract, entering the mucous membranes. Actually, the alpha particles that are associated with them can damage the DNA and become a significant source of pulmonary cancers by reproduction of this degraded DNA.

The residents of a house in which radon can accumulate and reach a volumetric activity that is hazardous to health have a high exposure because of confinement over long periods of time. In addition, the residences that are currently being built are increasingly insulated, and, in addition, the ventilation and the aeration of these dwellings are not always adequate.

Radon can enter dwellings in different ways, for example via cracks in the floor and walls and gaps between the walls and the floors because of the existing porosity in the walls.

Also, it has turned out to be very important to be able to measure radon and its daughter products in dwellings and premises that are open to the public and to monitor the change in levels.

The radon that is present in air is measured by its volumetric activity, expressed in becquerels per cubic meter. Thus, for sites that are open to the public, a known law provides a rate of 400 Bq/m³ as a limit of the volumetric activity that is acceptable for human health. Starting from 1,000 Bq/m³, intervention is necessary.

The law even makes provision for limiting the boundary rate to 200 Bq/m³ for new buildings.

Equipment for measuring radon is known, but it does not meet the needs of users or entities that are responsible for detection, monitoring, and interventions for eliminating the problems.

Thus, the patent U.S. Pat. No. 4,104,523 describes a device with a semi-conductor detector that makes it possible to count the alpha particles. The invention provides means for reducing the hygrometry level of the air surrounding said detector so as to protect it. Actually, this device is not very stable, is expensive, and is in particular difficult for private individuals to use.

The patent U.S. Pat. No. 5,029,248 describes a device for electrostatic capture and radon measurement. This device comprises a negative central electrode and a positive electrode, both arranged in one chamber. The positive electrode is in the form of a dome that is extended by walls in the shape of a truncated cone so as to concentrate the particles toward the negative electrode.

The negative electrode is covered by an electroconductive film that is permeable to alpha radiation.

The patent FR 2 728 691 relates to the measurement of radon 222 so as to produce standards.

There is also equipment that makes it possible to detect nuclear trace elements or an electrostatic discharge like electret ionization chambers, but it is disposable.

There is also a commercial monitor whose name is “Radim 3A,” which makes it possible to detect and to measure the radon level continuously, but it is cumbersome because of the fact that the electrode is to work under a dome, protected from light and photons. In addition, it is expensive, and its sensitivity is inadequate. The object of this invention is to propose a detector that can work in the open air, is simple, not cumbersome, able to record a large number of measurements and able to allow the reproduction thereof, with a cost that is compatible with the requirements of private individuals.

The detector according to this invention is now described relative to the accompanying drawings, in which the various figures show, in a nonlimiting manner:

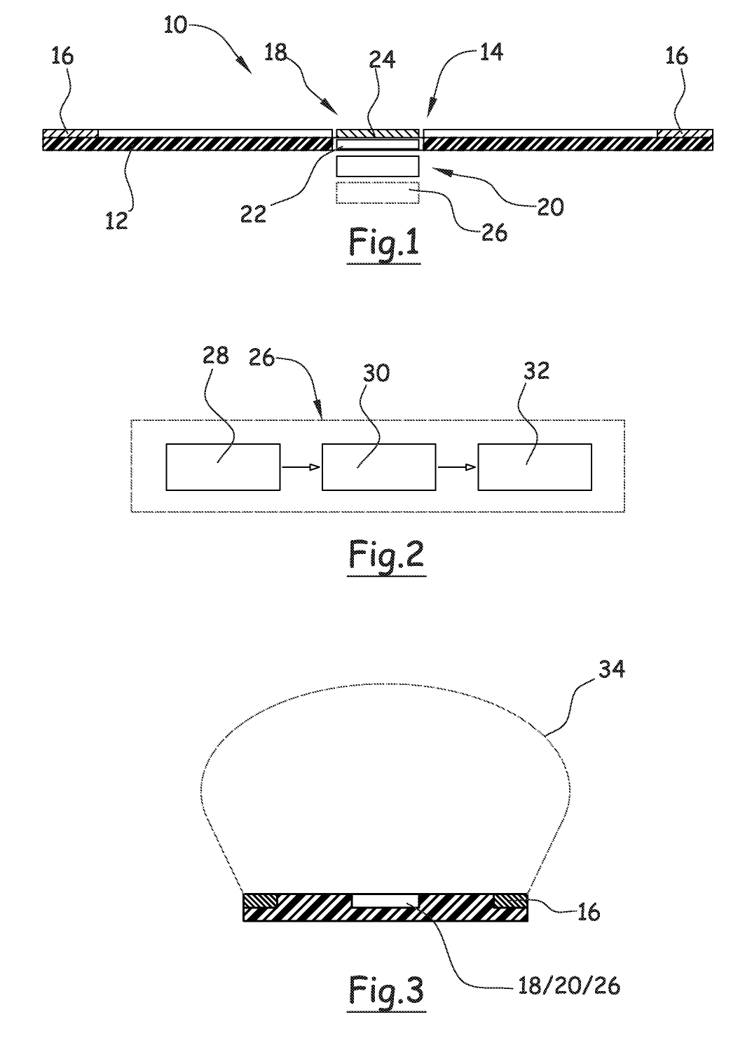

FIG. 1: A schematic diagrammatic view of the detector according to this invention;

FIG. 2: A view of the electronic signal processing circuit that is combined with the detector in such a way as to produce a detection device, and

FIG. 3: A variant embodiment.

FIG. 1 shows the detection device 10 according to this invention, in diagrammatic form, in a primary embodiment.

The detection device comprises a support 12 in the form of a disk made of insulating material, for example with a diameter of 5 to 50 cm. The thickness is based on the material, but it is necessary that the support be rigid.

This support 12 comprises a conductive electrode 16 that is a part of the means 14 for electrostatic collection of aerosols. This electrode 16 is advantageously a ring made of stainless steel, aluminum, copper or a coated metal such as steel with a vapor-phase-deposited layer or even a thin layer that is deposited directly on the support 12 that is made of insulating material.

This annular shape makes it possible to eliminate the sharp-point effects and to ensure perfect symmetry.

Within the adopted embodiment, the peripheral conductive electrode 16 is brought to the elevated potential of 10 to 2,000 volts to provide an order of magnitude, whereby this value is based on numerous parameters: geometry, distance between electrodes, and range of measured concentrations, as will be explained further.

The other so-called conductive collecting electrode 18, which is the other part of the means 14 for electrostatic collection of aerosols, is found at the center of the support 12 that is made of insulating material.

The conductive collecting electrode 18 is placed in a hole that is made in the support 12.

This conductive collecting electrode 18 according to the invention integrates a detector 20 that comprises a PN junction that is integrated on silicon with a deserted zone of 5 to 100 μm to provide an order of magnitude; the surface area of this electrode is 4 to 100 mm².

The thickness of this zone is based on the desired detection. The silicon pellet that integrates the detector 20 is covered by a passivation layer 22, in this case silica, and by a conductive layer 24 that constitutes the conductive electrode 18 itself.

This conductive layer 24, in the adopted embodiment, comprises a carbon layer with a thickness of 0.05 to 5 μm to which an aluminum layer with a thickness of 0.05 to 5 μm is added.

The electrode 18 that integrates the detector 20 is preferably arranged in such a way that its surface is within the plane of the insulating support 12.

The conductive collecting electrode 18 is brought to the base potential so as to collect radionuclides that are in particular conveyed by aerosols.

This is radiation that is emitted by these radio elements that can be collected by the detector 20.

It is noted that the electrode 18 synergetically ensures protection of the detector.

The signals that are emitted from this detector 20 and the device that includes it, under the action of nuclear radiation, are processed by an electronic circuit 26.

This circuit, shown diagrammatically and by way of example in FIG. 2, includes at least the following elements: a preamplifier 28 and a stage 30 for shaping the output pulse of the preamplifier to adapt it to the circuit and/or to the system for which it is designed.

This circuit can be integrated, of course, whereby the representation is only illustrative.

It is also possible to produce a differential amplifier that is designed to enhance the discrimination between the signal and the background noise, in particular the electronic noise that is generated by the circuit.

It is possible to include a discriminator 32 so as to be able to eliminate parasitic signals that are generated by gamma interactions and/or beta radiation.

It is also possible to delimit the analyzed gas volume by providing a perforated peripheral chamber 34 that surrounds the detector, as shown in FIG. 3.

In this case, the peripheral chamber 34 is conductive and brought to the top potential by contact with the electrode 16, whereby the volume of the chamber 34 can vary from 0.1 to 50 liters to provide an order of magnitude.

It is understood that the detector according to the invention has the advantage of being able to work in the open air and in the light because the passivation layer and the conductive layer as deposited ensure the protection of the PN junction that is made in the silicon while allowing the collection of charges that are desired, linked to an aerosol.

In the case of the detector according to this invention, even an increase in sensitivity is noted because certain charges are free, therefore not linked to an aerosol, but they are nevertheless collected by the conductive layer 24, and it is possible to collect the radiation that they emit.

In this case, the external electrode makes it possible to increase the detection volume.

According to an enhanced embodiment of the invention, the conductive layer 24 has rough spots at its interface with the air.

Thus, the collecting surface is increased, on the one hand, but primarily a multitude of sharp-point effects that contribute to increasing the collection very significantly are created.

These rough spots can be generated during the vapor phase deposition of metals of the collecting electrode 18, such as aluminum, if necessary by using masks.

The thickness of these rough spots is to remain below 1 micrometer.

So as to make the detection device compact, the invention provides integration by producing the unit in the form of an integrated circuit that is specific to this application, an ASIC.

In addition, the amplified and shaped charge pulses can be processed according to an analog/digital conversion to establish an energy spectrum of the radiation detected by the sensor.

It is also possible to add pulse-rise discriminators to the integrated circuits of the counters, if needed.

According to a miniaturized and optimized embodiment, the detector is connected to a stick of the USB (Universal Serial Bus) stick type. In this case, the stick ensures the recording and comprises means for connection and transfer of data obtained from the detector to display and/or interpretation software.

1. Detector (20) of radon and its daughter products that are present in the ambient air, including in particular aerosols, characterized in that it comprises:
A silicon pellet that integrates a PN junction with a deserted zone, designed to emit signals under the action of radiation that is emitted by said radon and said daughter products,
A passivation layer (22) that covers this silicon pellet and that makes it possible for the detector to work in the open air, and
A conductive layer (24) that covers the passivation layer and that forms an electrode for collecting radionuclides.

2. Radon detector (20) and its daughter products according to claim 1, wherein the conductive layer (24) has rough spots at its interface with the air.

3. Radon detector (20) and its daughter products according to claim 1, wherein the conductive layer (24) is a carbon layer with a thickness of 0.05 to 5 μm on top of which is an aluminum layer with a thickness of 0.05 to 5 μm, and the passivation layer is a silica layer, whereby the surface area is between 4 and 100 mm².

4. Device for detecting radon and its daughter products that are present in the ambient air, including in particular aerosols, comprising a detector (20) according to claim 1, wherein this device comprises:
A support (12) made of insulating material,
Means (14) for electrostatic collection of aerosols including a peripheral conductive electrode (16) and a conductive electrode (18) for central collection that is the conductive layer (24) of said detector (20),
An electronic circuit (26) for processing signals that are emitted from said detector.

5. Device for detecting radon and its daughter products according to claim 4, wherein the insulating support (12) is a disk, the peripheral conductive electrode (16) is a ring of conductive material, and the conductive collecting electrode (18) that integrates the detector (20) is placed in a hole that is made in this insulating support (12).

6. Device for detecting radon and its daughter products according to claim 4, wherein the electrode (18) that integrates the detector (20) is arranged in such a way that its surface is in the plane of the insulating support (12).

7. Device for detecting radon and its daughter products according to claim 4, wherein it comprises a perforated, peripheral conductive chamber (34) that surrounds the detector (20) and that is in contact with the peripheral conductive electrode (16).

8. Device for detecting radon and its daughter products according to claim 4, wherein the electronic processing circuit (26) comprises a preamplifier (28) and a stage (30) for shaping the output pulse of the preamplifier for adapting it to the circuit and/or the system for which it is designed.

9. Device for detecting radon and its daughter products according to claim 4 wherein it comprises a differential amplifier that is designed to enhance the discrimination between the signal and the background noise.

10. Device for detecting radon and its daughter products according to claim 4, wherein it comprises a discriminator (32) so as to be able to eliminate the parasitic signals that are generated by the gamma interactions and/or the beta radiation.

11. Radon detector (20) and its daughter products according to claim 2, wherein the conductive layer (24) is a carbon layer with a thickness of 0.05 to 5 μm on top of which is an aluminum layer with a thickness of 0.05 to 5 μm, and the passivation layer is a silica layer, whereby the surface area is between 4 and 100 mm².

12. Device for detecting radon and its daughter products that are present in the ambient air, including in particular aerosols, comprising a detector (20) according to claim 2, wherein this device comprises:
A support (12) made of insulating material,
Means (14) for electrostatic collection of aerosols including a peripheral conductive electrode (16) and a conductive electrode (18) for central collection that is the conductive layer (24) of said detector (20), An electronic circuit (26) for processing signals that are emitted from said detector.

13. Device for detecting radon and its daughter products that are present in the ambient air, including in particular aerosols, comprising a detector (20) according to claim 3, wherein this device comprises:
A support (12) made of insulating material,
Means (14) for electrostatic collection of aerosols including a peripheral conductive electrode (16) and a conductive electrode (18) for central collection that is the conductive layer (24) of said detector (20), An electronic circuit (26) for processing signals that are emitted from said detector.

14. Device for detecting radon and its daughter products according to claim 5, wherein the electrode (18) that integrates the detector (20) is arranged in such a way that its surface is in the plane of the insulating support (12).

15. Device for detecting radon and its daughter products according to claim 5, wherein it comprises a perforated, peripheral conductive chamber (34) that surrounds the detector (20) and that is in contact with the peripheral conductive electrode (16).

16. Device for detecting radon and its daughter products according to claim 6, wherein it comprises a perforated, peripheral conductive chamber (34) that surrounds the detector (20) and that is in contact with the peripheral conductive electrode (16).

17. Device for detecting radon and its daughter products according to claim 5, wherein the electronic processing circuit (26) comprises a preamplifier (28) and a stage (30) for shaping the output pulse of the preamplifier for adapting it to the circuit and/or the system for which it is designed.

18. Device for detecting radon and its daughter products according to claim 6, wherein the electronic processing circuit (26) comprises a preamplifier (28) and a stage (30) for shaping the output pulse of the preamplifier for adapting it to the circuit and/or the system for which it is designed.

19. Device for detecting radon and its daughter products according to claim 7, wherein the electronic processing circuit (26) comprises a preamplifier (28) and a stage (30) for shaping the output pulse of the preamplifier for adapting it to the circuit and/or the system for which it is designed.

20. Device for detecting radon and its daughter products according to claim 5 wherein it comprises a differential amplifier that is designed to enhance the discrimination between the signal and the background noise.
